(19) United States
(12) Patent Application Publication
(10) Pub. No.: US 2024/0206047 A1
(43) Pub. Date: Jun. 20, 2024

(54) ELECTRONIC ASSEMBLY, LIGHT MODULE, AND METHOD FOR CONSTRUCTING AN ELECTRONIC ASSEMBLY

(71) Applicant: HELLA GmbH & Co. KGaA, Lippstadt (DE)

(72) Inventors: Sebastian BARTSCHER, Hamm (DE); Werner KOESTERS, Coesfeld-Lette (DE); Michael LAKENBRINK, Oelde (DE); Thomas WIESE, Lippstadt (DE)

(73) Assignee: HELLA GmbH & Co. KGaA, Lippstadt (DE)

(21) Appl. No.: 18/542,599

(22) Filed: Dec. 16, 2023

(30) Foreign Application Priority Data
Dec. 19, 2022 (DE) 10 2022 133 820.7

(51) Int. Cl. H05K 1/02; F21S 41/153; H05K 3/00; H05K 7/20

(52) U.S. Cl. CPC H05K 1/0204; F21S 41/153; H05K 3/002; H05K 7/20172; F21Y 2115/10; H05K 2201/10106

(57) ABSTRACT

An electronic assembly having at least one electronic component, in particular a light-emitting diode, and a printed circuit board. The printed circuit board has a substrate, conductive traces, and at least one solder pad. The electronic component is held on the solder pad by a solder joint. The substrate has, on a back opposite the electronic component, a micro-cooling structure, wherein the micro-cooling structure is designed as an arrangement of recesses in the back of the substrate in such a manner that the micro-cooling structure is configured to dissipate heat from the electronic component.

This nonprovisional application claims priority under 35 U.S.C. § 119(a) to German Patent Application No. 102022133820.7, which was filed in Germany on Dec. 19, 2022, and which is herein incorporated by reference.

### BACKGROUND OF THE INVENTION

### Field of the Invention

The present invention relates to an electronic assembly comprising at least one electronic component, in particular a light-emitting diode, and a printed circuit board, wherein the printed circuit board has a substrate, conductive traces, and at least one solder pad, and wherein the electronic component is held on the solder pad by means of a solder joint. In addition, the invention relates to an associated light module and to a method for constructing the electronic assembly.

### Description of the Background Art

In numerous applications, electronic assemblies of the aforementioned type are equipped with powerful electrical loads as electronic components, for example with light-emitting diodes for light modules of motor vehicle lighting devices. Removal of the heat released in operation of the electronic components represents a significant challenge. It is customary in the prior art to solder or adhesively bond the full area of the back of the substrate of the printed circuit board to a metallic heat sink so that the operating heat is conducted into the heat sink and can be emitted to the operating environment therethrough, in particular in combination with a fan directed at the heat sink. The use of such heat sinks leads to a disadvantageous increase in the installation space required by the assembly.

### SUMMARY OF THE INVENTION

It is therefore an object of the present invention to provide an improvement of an electronic assembly of the abovementioned type and a method for constructing the same, wherein the assembly, complete with the elements provided for heat dissipation, should have comparatively small dimensions.

In an example, provides that a substrate of a printed circuit board has, on a back opposite the electronic component, a micro-cooling structure, wherein the micro-cooling structure is designed as an arrangement of recesses in the back of the substrate in such a manner that the micro-cooling structure is configured to dissipate heat from the electronic component.

The fundamental idea of the invention is in increasing the free surface of the substrate with the formation of the micro-cooling structure in such a manner that the heat that can be emitted therethrough to the operating environment leads to a sufficient dissipation of heat from the electronic component, and therefore a separate heat sink can be dispensed with. Provided that sufficient mechanical stability of the substrate is maintained, the micro-cooling structure can cover the entire back of the substrate. Alternatively, the micro-cooling structure has a lateral extent that corresponds essentially to a lateral extent of the electronic component, and therefore constitutes a dedicated local heat dissipater.

The recesses in the micro-cooling structure preferably expose surfaces of a metallic constituent of the substrate of the printed circuit board. For example, the substrate is designed as a so-called “insulated metal substrate (IMS)” and comprises a metal plate, composed of copper or aluminum, for example, and an insulating layer, wherein the insulating layer electrically insulates the conductive traces and the at least one solder pad from the metal plate, and wherein the micro-cooling structure is arranged in the metal plate. Alternatively, the substrate comprises an electrically insulating substrate body, made of a fiber-reinforced epoxy resin, for example, and at least one metallic heat-dissipating element arranged in the substrate body, wherein the micro-cooling structure is arranged in the heat-dissipating element so that the heat-dissipating element is exposed on the back.

The micro-cooling structure according to the invention can be incorporated in any type of printed circuit board, in particular in single-sided as well as double-sided or multilayer printed circuit boards.

The recesses in the micro-cooling structure have the form of grooves running in straight lines, in curves, or in circles. The sides of the grooves form additional free surfaces that serve to emit heat to the operating environment. For example, the recesses have the form of grooves running in circles in a concentric or gridlike arrangement.

In particular, the recesses in the micro-cooling structure can have a depth in the range of 10 micrometers-1 millimeter and/or a width in the range of 5-500 micrometers. The dimensions with respect to recess depth and width, and the form and the lateral extent of the micro-cooling structure are each matched to the specific assembly, in particular while taking into account the construction of the printed circuit board, the thickness of the substrate, the size and number of electronic components, and the heat output to be removed. Another aspect for designing the micro-cooling structure relates to thermal management in the application addressed, which is to say the installation situation and the possible presence of active fans. The aspect ratio of the recesses can advantageously be arranged such that a chimney effect is created in heat dissipation operation, increasing the cooling capacity.

The invention additionally relates to a light module for a motor vehicle lighting device, comprising an electronic assembly in accordance with one of the abovementioned embodiments, wherein the at least one electronic component is designed as a light-emitting diode. For example, the light module is designed as an LED matrix light module, and the assembly comprises a multiplicity of light-emitting diodes in a regular arrangement, wherein a separate micro-cooling structure can be associated with each light-emitting diode or the entire back of the substrate of the printed circuit board facing away from the light-emitting diodes has one unified micro-cooling structure.

The light module comprises at least one micro fan that is configured to dissipate heat from the at least one micro-cooling structure. As a result, powerful heat dissipation for the light-emitting diode is provided together with small installation dimensions of the light module.

In addition, the invention relates to a method for constructing an electronic assembly according to the invention, comprising at least the following steps in an order that is not fixed: providing a printed circuit board, wherein the printed circuit board has a substrate and at least one solder pad, producing at least one micro-cooling structure as an arrangement of recesses in the back of the substrate by means of machining, for example sawing or milling, by means of laser structuring, or by means of chemical etching, and soldering an electronic component, in particular a light-emitting diode, onto the at least one solder pad.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a schematic cross-sectional view of an example of the assembly according to the invention,

FIG. 2 shows a schematic cross-sectional view of an example assembly,

FIG. 3 shows a schematic cross-sectional view of an example assembly, and

FIGS. 4a to 4c show schematic top views of embodiments of micro-cooling structures.

### DETAILED DESCRIPTION

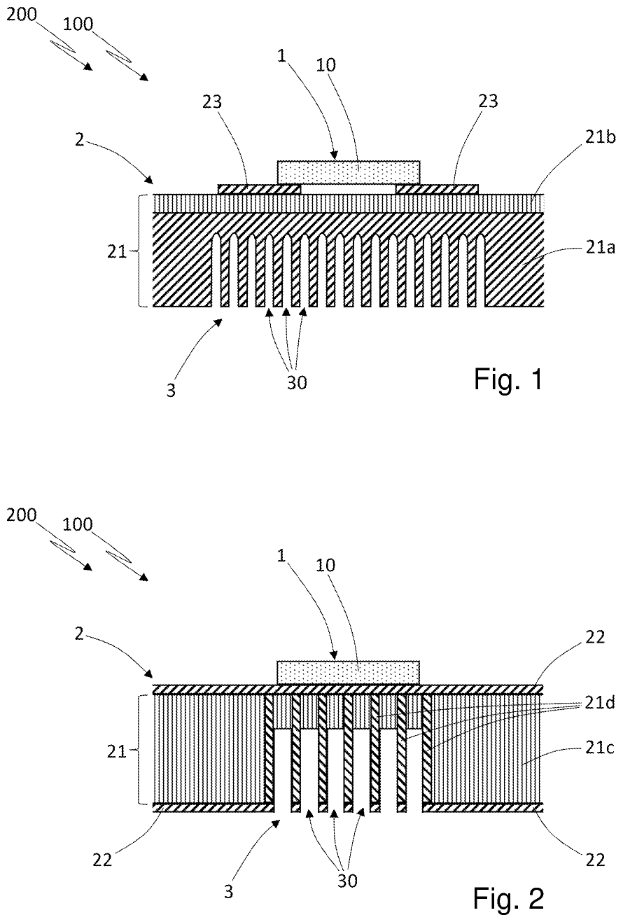

FIG. 1-FIG. 3 show schematic cross-sectional views of different exemplary embodiments of light modules 200 according to the invention with electronic assemblies 100 according to the invention. The assemblies 100 each comprise the electronic component 1 in the form of a light-emitting diode 10, and the printed circuit board 2, wherein the printed circuit board 2 has the substrate 21, the conductive traces 22, and/or the solder pad 23, on which the light-emitting diode 10 is held by means of a solder joint. According to the invention, the substrate 21 has, on its back opposite the light-emitting diode 10 in each case, the micro-cooling structure 3, wherein the micro-cooling structure 3 is designed as an arrangement of recesses 30 in such a manner that the micro-cooling structure 3 is configured to dissipate heat from the light-emitting diode 10.

The free surface of the substrate 21 is increased significantly in the region of the micro-cooling structure 3, a circumstance that results in improved heat dissipation performance as compared with an unstructured surface. The recesses 30 have a groove-like form whose detailed contour is dependent, in particular, on the method used to make them, for example mechanical machining, laser structuring, or chemical etching.

In the exemplary embodiment from FIG. 1, the substrate 21 is designed as an IMS and comprises the metal plate 21a, composed of copper or aluminum, for example, and the insulating layer 21b, which electrically insulates the solder pad 23 from the metal plate 21a, wherein the micro-cooling structure 3 is arranged in the back of the metal plate 21a.

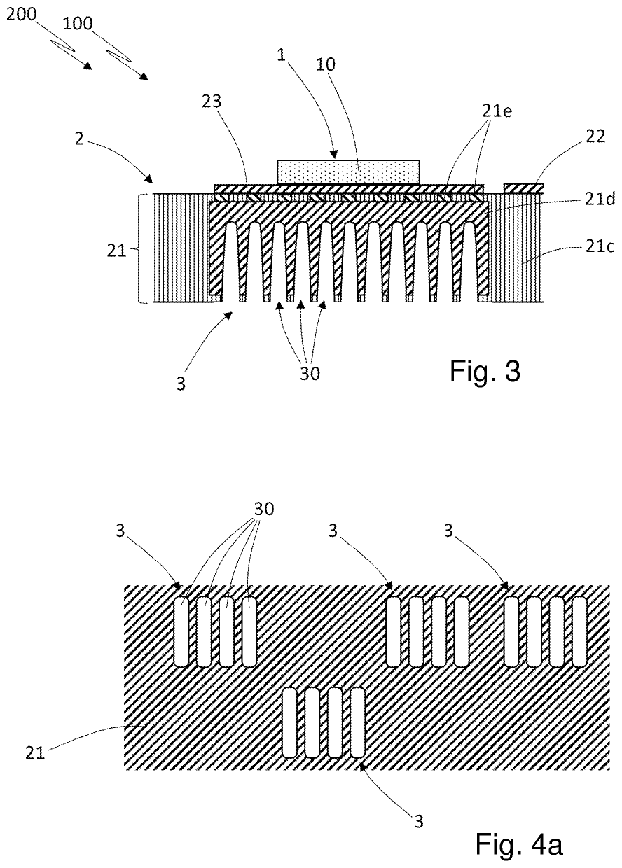

In the exemplary embodiments from FIG. 2 and FIG. 3, the substrate 21 comprises the electrically insulating substrate body 21c, made of a fiber-reinforced epoxy resin, for example, and the metallic heat-dissipating element 21d arranged therein, wherein the micro-cooling structure 3 is arranged in the heat-dissipating element 21d so that the heat-dissipating element 21d is exposed on the back for the purpose of heat emission. In the exemplary embodiment from FIG. 3, the heat-dissipating element 21d is connected in a thermally conductive manner to the solder pad 23 by the metallic thermal bridge elements 21e.

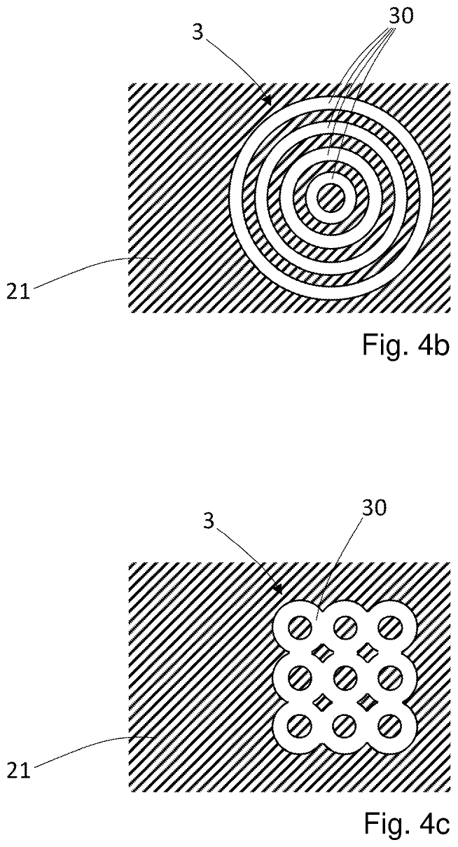

FIG. 4a-FIG. 4c show schematic top views of different embodiments of micro-cooling structures 3 on the back of a substrate 21 as part of an assembly according to the invention.

FIG. 4a shows four micro-cooling structures 3 that are spaced apart from one another whose recesses 30 have the form of grooves running in straight lines and parallel to one another. Each of the four micro-cooling structures 3 is configured to dissipate heat from one electronic component each on the opposite front side of the substrate 21.

FIG. 4b shows a micro-cooling structure 3 whose recesses 30 have the form of grooves running in circles in a concentric arrangement.

FIG. 4c shows a micro-cooling structure 3 whose recesses 30 have the form of grooves running in circles in a gridlike arrangement, by which means a regular grid of pegs projecting between the groove bottoms is formed.

The invention is not limited in its implementation to the preferred exemplary embodiment provided above. Instead, a number of variants are possible that make use of the described solution even in embodiments that are fundamentally different in nature. All features and/or advantages, including design details and spatial arrangements, that derive from the claims, the description, or the drawings, can be essential for the invention individually as well as in a wide variety of combinations.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. An electronic assembly comprising:
at least one electronic component;
a printed circuit board having a substrate, conductive traces, and at least one solder pad, the electronic component being held on the solder pad via a solder joint; and
a micro-cooling structure arranged on a back of the substrate that is opposite the electronic component, the micro-cooling structure being formed as an arrangement of recesses in the back of the substrate such that the micro-cooling structure is configured to dissipate heat from the electronic component.

2. The electronic assembly according to claim 1, wherein the recesses have the form of grooves running in straight lines, in curves, or in circles.

3. The electronic assembly according to claim 1, wherein the recesses have the form of grooves running in circles in a concentric or gridlike arrangement.

4. The electronic assembly according to claim 1, wherein the recesses have a depth in the range of 10 micrometers to 1 millimeter and/or a width in the range of 5 to 500 micrometers.

5. The electronic assembly according to claim 1, wherein the micro-cooling structure has a lateral extent that corresponds essentially to a lateral extent of the electronic component.

6. The electronic assembly according to claim 1, wherein the substrate comprises a metal plate and an insulating layer, wherein the insulating layer electrically insulates the conductive traces and the at least one solder pad from the metal plate, and wherein the micro-cooling structure is arranged in the metal plate.

7. The electronic assembly according to claim 1, wherein the substrate comprises an electrically insulating substrate body and at least one metallic heat-dissipating element arranged in the substrate body, and wherein the micro-cooling structure is arranged in the heat-dissipating element.

8. A light module for a motor vehicle lighting device, the light module comprising an electronic assembly according to claim 1, wherein the at least one electronic component is a light-emitting diode.

9. The light module according to claim 8, wherein the light module comprises at least one micro fan that is configured to dissipate heat from the at least one micro-cooling structure.

10. A method to construct an electronic assembly according to claim 1, the method comprising:
providing a printed circuit board having a substrate, conductive traces, and at least one solder pad;
producing at least one micro-cooling structure as an arrangement of recesses in the back of the substrate by machining, by laser structuring, or by chemical etching; and
soldering the electronic component onto the at least one solder pad.

11. The electronic assembly according to claim 1, wherein the at least one electronic component is a light-emitting diode.
